(19) United States
(12) Patent Application Publication
(10) Pub. No.: US 2009/0026499 A1
(43) Pub. Date: Jan. 29, 2009

(54) SEMICONDUCTOR INTEGRATED CIRCUIT DEVICE AND SEMICONDUCTOR SWITCHING DEVICE USING THEREOF

(76) Inventors: Takeshi Kikawa, Kodaira (JP); Shinichiro Takatani, Musashino (JP); Tomihisa Yukimoto, Hitachi (JP); Yohei Otoki, Hitachi (JP); Hiroyuki Kamogawa, Hitachi (JP); Tomoyoshi Mishima, Shiki (JP)

Correspondence Address: MILES & STOCKBRIDGE PC, 1751 PINNACLE DRIVE, SUITE 500, MCLEAN, VA, 22102-3833, US

(21) Appl. No.: 12/019,137

(22) Filed: Jan. 24, 2008

(30) Foreign Application Priority Data
Jul. 23, 2007 (JP) 2007-190778

(51) Int. Cl. H01L 29/78

(52) U.S. Cl. 257/194; 257/E29.246

(57) ABSTRACT

A semiconductor integrated circuit device having a plurality of semiconductor electronic members including a field effect transistor, intended for suppressing a sidegating effect on the field effect transistor, wherein accumulation of majority carriers of the field effect transistor is suppressed at the interface of heterojunction in the buffering compound semiconductor layer and the interface between the substrate and the buffering compound semiconductor layer in the device isolation region so that the discontinuity of energy forbidden bands of the semiconductors caused at the interfaces does not form a potential barrier upon conduction of the carriers into the substrate, whereby the sidegating effect from the resistor element, etc. placed adjacently to the field effect transistor can be decreased drastically.

### CLAIM OF PRIORITY

The present application claims priority from Japanese application JP 2007-190778 filed on Jul. 23, 2007, the content of which is hereby incorporated by reference into this application.

### FIELD OF THE INVENTION

The present invention is related to a semiconductor integrated circuit device having a plurality of semiconductor electronic members including a field effect transistor. The invention has an effect of suppressing a sidegating effect on the field effect transistor, and more in particular, it is useful when applied to a semiconductor switching device using the semiconductor integrated circuit device described above.

### BACKGROUND OF THE INVENTION

A compound semiconductor device using a compound semiconductor such as gallium arsenite (GaAs), indium phosphite (InP), and gallium nitride (GaN) for a substrate or an under layer has higher electron mobility compared with a silicon (Si) device and is used frequently for devices requiring high speed, high frequency, and high efficiency operation. A typical example is a high frequency switch.

The high frequency switch is used for switching transmission and reception in wireless communication equipment such as mobile telephones or wireless LANs (local area networks). Depending on the system, it conducts switching signals with several Watts or higher. Along with diversification of wireless communication, a switch for switching a plurality of transmission and reception sections for one antenna has been put to practical use.

The high frequency switch includes a switch using a diode and a switch using a field effect transistor. The field effect transistor switch has an advantage of less power consumption and higher manufacturability of a complicate switch circuit, compared with the diode switch.

The field effect transistor switch is a semiconductor monolithic integrated device prepared by monolithically integrating a plurality of transistors, resistor elements, etc. The monolithic integrated device described above has resulted in a problem so far with a so-called sidegating effect in which voltages and signals of adjacent electronic members, for example, elements or wiring are mutually influenced, adversely affecting device characteristics. Japanese Unexamined Patent Application 5-275474 discloses that the sidegating effect can be suppressed by forming an isolate semiconductor layer of floating potential between adjacent field effect transistors with an aim of decreasing the sidegating effect. Further, Japanese Unexamined Patent Application No. 10-163434 discloses that mutual electrical interference between each of electric elements can be prevented by disposing buffer layers in different regions on a substrate respectively and forming one electric element on one buffer layer.

### SUMMARY OF THE INVENTION

The sidegating effect in conventional integrated devices has led to a problem with low frequency response such as low frequency oscillation phenomena in the digital application. This is caused by propagation of potential through a deep energy level referred to as EL2 in a substrate.

On the other hand, in the analog switch application, a high-frequency voltage with a frequency of 1 GHz or higher and with an amplitude of ±10 V or more is applied between an on transistor and a resistor disposed in the vicinity thereof. Since the response speed of propagation in the substrate by way of a deep energy level is slow, there may be less risk that such high-frequency signals propagate in the substrate.

However, the present inventors have found that the sidegating effect due to the propagation of potential through the buffer layer with no deep energy level such as EL2 raises another problem of generating harmonic distortion to antenna output signals. When high-frequency potential propagates from the sidegate through the buffer layer to the channel of the transistor, the electric conductivity of the channel undergoes modulation to generate harmonic distortion. Further, mutual modulation distortion that is a problem, for example, in a wide-band CDMA (Code Division Multiplet Access) system mobile telephone also occurs.

Various kinds of buffer layers 202 of conventional structures were epitaxially grown on a GaAs substrate 201, and characteristics of integrated devices using the same were compared. Examples of various buffer layers of the conventional structures are as shown in Table 1.

TABLE 1

| | Name for | | | |
|---|---|---|---|---|
| | epitaxial | Carrier | | |
| Material | layer | concentration | Thickness | |
| un- | AlGaAs buffer | ≦1 × 10¹⁶ cm⁻³ | 200 nm | |
| AlGaAs | layer | | | |
| un-GaAs | 4-period MQW | ≦1 × 10¹⁵ cm⁻³ | 50 nm | ×4 |
| un- | buffer layer | ≦1 × 10¹⁶ cm⁻³ | 50 nm | periods |
| AlGaAs | | | | |
| un-GaAs | GaAs buffer | ≦1 × 10¹⁵ cm⁻³ | 200 nm | |
| | layer | | | |
| p-AlGaAs | Substrate | 1 × 10¹⁷ cm⁻³ | 10 nm | |
| | interface | | | |
| | layer | | | |
| GaAs | Substrate | | | |

Disposed on the buffer layer are an HEMT (High Electron Mobility Transistor) device 203 prepared by epitaxially growing an HEMT structure and a mesa resistor element 204 formed by disposing the resistor element adjacently to the HEMT device 203 and etching them. FIG. 2 is a cross sectional view of this integrated device. In this embodiment, a p-typed AlGaAs interface layer is disposed between the substrate 201 and the buffer layer 202.

A device isolation region 205 is disposed between the HEMT device 203 and the mesa-resistor element 204 adjacent thereto. FIG. 3 shows the dependence of the magnitude of the sidegating effect on the groove depth of the device isolation region 205. The depth of the groove 205 is shown on the horizontal axis as a quantity of the buffer layer left in a region where the buffer layer 202 is left and as a etching quantity of the substrate in a case where the groove reaches as deep as the inside of the substrate. A quantity of change of the sidegating effect is shown in an arbitrary unit on the vertical axis. “Five MQW (Multiplet Quantum Well) layers left,” “Three MQW layers left,” and “MQW removed,” show the results in cases of leaving five MQW layers, leaving three MQW layers and removing all MQW layers respectively.

Compared with the case where the device isolation region 205 reaches the substrate 201, when a portion of the buffer layer 202 is left in the device isolation region 205, the sidegating effect increases. This indicates that the sidegating effect is caused due to the propagation of the potential through the buffer layer 202.

Such being the background, the present invention is intended to suppress the sidegating effect on the field effect transistor in a semiconductor integrated circuit device having a plurality of semiconductor electronic members including a field effect transistor.

The semiconductor integrated circuit device described above can suppress the sidegating effect due to the propagation of the potential by way of the buffer layer in the application to analog switches and can provide a device structure for realizing a field effect transistor switch with less harmonic distortion in antenna output signals.

The foregoing problem can be overcome by suppressing propagation of potential through a buffering compound semiconductor layer. The present inventors have found that the following constitution is important for suppressing the propagation of potential through a buffering compound semiconductor layer. That is, it is necessary to prevent accumulation of carriers in a buffering compound semiconductor layer remaining in a device isolation region, for example, between a resistor element and a transistor adjacent thereto and to move carriers to a substrate without the carriers staying in the buffering compound semiconductor layer. For this purpose, it is necessary that the discontinuity of energy forbidden bands of semiconductors formed at a interface of heterojunction in the buffering compound semiconductor layer and an interface between the substrate and the buffering compound semiconductor layer does not form a potential barrier upon conduction of majority carriers to the substrate.

That is, conduction of the potential of the buffering compound semiconductor layer can be suppressed, that is, the sidegating effect can be suppressed by adopting a semiconductor structure where the discontinuity of conduction band edges at the interface of heterojunction does not form a potential barrier upon the electron conduction, or the discontinuity at the valance band edges does not form a potential barrier upon hole conduction in a device isolation region disposed between adjacent devices.

In the present specification, the buffering compound semiconductor layer refers to a semiconductor layer epitaxially grown adjacently to a substrate, not intended for generation, coupling, supply, injection, conduction, rectification, or amplification of carriers, or not intended for generation of resistance, capacitance, and electromagnetic induction. Further, a portion or the entire portion of the semiconductor layer right underneath a channel layer is shown when a field effect transistor is formed succeeding to the formation of the buffering compound semiconductor layer, or right underneath a carrier supply layer in a case where the carrier supply layer is formed to the side nearer to the substrate than the channel layer.

Further, in the present specification, the electronic members mean various members for constituting the semiconductor integrated circuit device, which also include active devices such as the transistors and passive devices such as the resistors as described above.

According to the invention, the sidegating effect on the field effect transistor can be suppressed in a semiconductor integrated circuit device having a plurality of semiconductor electronic members including a field effect transistor. With the use of the semiconductor integrated circuit device, a semiconductor switching device in which the sidegating effect is sufficiently suppressed can be provided.

### BRIEF DESCRIPTION OF THE DRAWINGS

FIG. 1 is a cross-sectional view showing a first embodiment of the invention;

FIG. 2 is a cross-sectional view showing an embodiment of a field effect transistor switch of a conventional structure;

FIG. 3 is a graph explaining the sidegating effect on a field effect transistor switch of a conventional structure;

FIG. 4 is a graph explaining the effect of the invention;

FIG. 5 is a cross sectional view showing a second embodiment of the invention; and

FIG. 6 is a cross sectional view showing a third embodiment of the invention.

### DETAILED DESCRIPTION OF THE PREFERRED EMBODIMENT

Before explaining various embodiments of the invention, main constitutions of the invention are set forth and described.

(1) A semiconductor integrated circuit device at least having, above a substrate, a field effect transistor as a first electronic member and a second electronic member mounted in juxtaposition and an inter-device isolation region between the field effect transistor and the second electronic member by way of a buffering compound semiconductor layer, in which

the buffering semiconductor layer is formed to have a thickness smaller than those in other regions, or the buffering compound semiconductor layer is not present in the inter-device isolation region, and discontinuity of electrostatic potential formed at the hetero-compound semiconductor junction interface, which is at least either of the interface between the buffering semiconductor layer and the semiconductor substrate or the interface between the compound semiconductor layers constituting the buffering compound semiconductor layer, is such that the electrostatic potential of the buffering compound semiconductor layer on the side of the substrate is lower than the potential on the side opposite to the substrate for majority carriers during operation of the field effect transistor.

The inter-device isolation region can be obtained, for example, by forming a so-called device isolation region with a groove or ion implantation to a semiconductor layer, that is:

(2) the semiconductor integrated circuit device according to (1) described above, wherein the inter-device isolation region is a groove, and the buffering compound semiconductor layer at the bottom of the groove is formed to have a thickness smaller than those in other regions, or the buffering compound semiconductor layer is not present, or

(3) the semiconductor integrated circuit device according to (2) as described above, wherein the inter-device isolation region is a device isolation region formed by ion implantation, and the buffering compound semiconductor layer present in the device isolation region on the side of the substrate is formed to have a thickness smaller than those in other regions,

(4) in the device isolation region formed by the ion implantation, the peak concentration of implanted ions is actually 1×10¹⁷ cm⁻³ or more. Actually, the peak concentration may be at this level irrespective of semiconductor materials, and this is to be descried further in examples. Further, also ion species are to be described later,

(5) usually, ions for the ion implantation is preferably at least one member selected from the group consisting of oxygen ions, boron ions, helium ions, nitrogen ions, chromium ions, iron ions, and ruthenium ions,

(6) a case of using hydrogen ions or fluorine ions for ion implantation necessitates conditions different from those for each of the ions described above. That is, upon forming the device isolation region by the ion implantation, when the ions for ion implantation are at least one member selected from the group consisting of hydrogen ions and fluorine ions, the buffering compound semiconductor layer at least in the inter-device isolation region is constituted so as not to include a quantum well structure.

For the width of the inter-device isolation region, a typical range from 5 μm to 20 μm is used frequently. Further, for the thickness of the buffering compound semiconductor layer, a thickness used usually may be sufficient. For example, for the thickness, a range from 200 nm to 800 nm is suitable.

While an example has been described above, various constitutions can be adopted for the buffering compound semiconductor layer. That is;

(7) first, the buffering compound semiconductor layer at least in the inter-device isolation region has a first compound semiconductor layer, a compound semiconductor layer of a multi-layer quantum well structure, and a second compound semiconductor layer.

(8) secondly, the previously shown buffering compound semiconductor layer at least in the inter-device isolation region has a plurality of compound semiconductor layers not including a quantum well structure,

(9) thirdly, the buffering compound semiconductor layer at least in the inter-device isolation region has a single compound semiconductor layer. Also in this case, it is of course important that the discontinuity of the electrostatic potential at the hetero-compound semiconductor junction interface formed at the interface between the buffering semiconductor layer and the semiconductor substrate is such that the electrostatic potential of the buffering compound semiconductor layer on the side of the substrate is lower than the potential on the side opposite to the substrate for majority carriers during operation of the field effect transistor.

Various kinds of substrates can be used for practicing the invention. Typical examples are a GaAs substrate, an InP substrate, and a GaN substrate. Further, depending on the selection of semiconductor materials, they can also include a sapphire substrate, a silicon carbide substrate, a silicon substrate, etc. For the buffering compound semiconductor layer, those materials used so far particularly in the field of compound semiconductor devices can be used. They are of course set so as to satisfy the conditions of the electrostatic potential at the hetero-compound semiconductor junction interface associated with the invention. From a practical point of view, more preferred examples for the substrate and the buffering compound semiconductor layer are shown below.

(10) the first example of the substrate is a GaAs substrate, in which the buffering compound semiconductor layer at least in the inter-device isolation region is at least one member selected from the group of GaAs, AlGaP, InGaP, and InGaAlP.

(11) the second example of the substrate is an InP substrate, in which the buffering compound semiconductor layer at least in the inter-device isolation region is at least one member selected from the group of AlInAs, GaInAs, AlGaInAs, GaInAsP, and AlGaInAsP.

(12) the third example is a substrate selected from the group consisting of a GaN substrate, a sapphire substrate, a silicon carbide substrate, and a silicon substrate in which the buffering compound semiconductor layer at least in the inter-device isolation region is at least one member selected from the group of GaN, AlN, and AlGaN.

(13) the most useful example of the field effect transistor as the first electronic member is an HEMT (high electron mobility transistor).

The outline of a typical method of manufacturing the semiconductor integrated circuit device according to the invention is as described below.

In the manufacturing method, when a buffering compound semiconductor layer is present at least below the first and the second electronic members and, further, at the bottom of the device-isolation region, such buffering compound semiconductor layers are a common semiconductor layer. That is, the method includes at least a step of forming a buffering compound semiconductor layer on a substrate, a step of forming at least a main portion of a first electronic member, for example, a main portion of a field effect transistor on the buffering compound semiconductor layer, a step of forming a device isolation region in a region adjacent to the first electronic member, and a step of forming a second electronic member adjacent to the device isolation region. The device isolation region can be prepared, for example, by a groove or an ion implantation region as described above. Also, in the region corresponding to the device isolation region, the buffering compound semiconductor layer may be removed entirely or removed partially while leaving a portion. Further, the order of the forming steps for the first and the second electronic members and the device isolation region can be selected irrespective of the order described above.

Further, for forming the second electronic member, for example, a semiconductor layer for forming the first electronic member formed previously may be used, the semiconductor layer may be used while removing a portion thereof, or the semiconductor layer may be removed partially or entirely and a semiconductor layer for forming the second electronic member may be formed again thereabove.

### First Embodiment

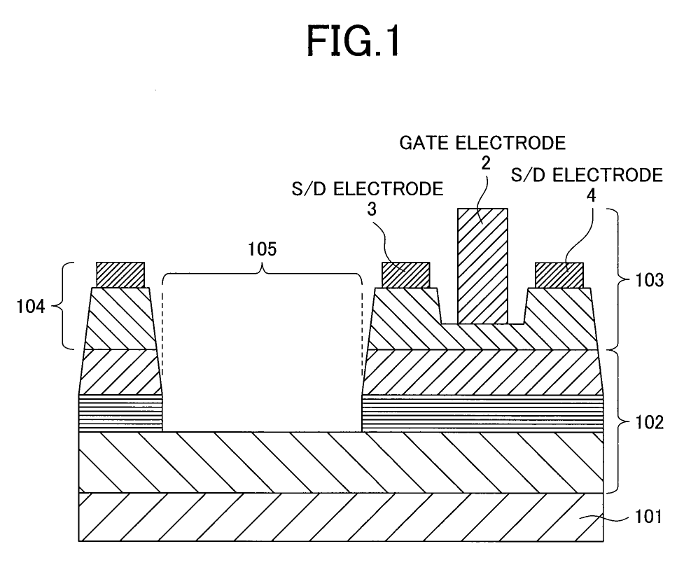

An example for practicing the invention is to be described with reference to FIG. 1. FIG. 1 is a cross sectional view of a main portion of an integrated device of this embodiment. This is an example of a 3-hierarchized structure using a buffer layer in which an MQW (Multi-quantum well) structure is also inserted as a first hierarchical layer thereof. That is, this embodiment is an HEMT switch manufactured by forming a buffer layer 102 of a GaAs/AlGaAs laminate structure on a GaAs substrate 101, on the surface of which buffer layer a pseudomorphic HEMT (PHEMT) device 103 having a channel composed of InGaAs and a resistor element 104 adjacent thereto are integrated. The planar arrangement of a field effect transistor and a resistor element of the semiconductor integrated circuit device can sufficiently be configured in a typical manner. For example, in a case of the field effect transistor, a source, gate and drain are each in a rectangular shape and juxtaposed sequentially. Further, a multi-flexed gate may also be used. This also applies to each of the following embodiments.

In each of the following embodiments, the term for the buffering compound semiconductor layers used in the previous explanation is simply referred to merely as a buffer layer.

According to this example, the sidegating effect in the semiconductor integrated circuit device can be suppressed also in a case of using a buffer layer including the MQW structure.

Table 2 shows the structure of the buffer layer. A buffer layer 202 is formed by stacking the following three types of layers. That is, the buffer layer 202 is structured by forming a GaAs buffer layer 202-1 with a 200 nm thickness on a GaAs substrate 101, a 4-period MQW buffer layer 202-2 composed of AlGaAs/GaAs (AlGaAs/GaAs has a form in which AlGaAs layers and GaAs layers are stacked alternately) with a 50 nm thickness for each ALGaAs and GaAs layer thereon, and an AlGaAs buffer layer 202-3 with a 200 nm thickness further thereon.

TABLE 2

| | Name for | | | |
|---|---|---|---|---|
| | epitaxial | Carrier | | |
| Material | layer | concentration | Thickness | |
| un- | AlGaAs buffer | ≦1 × 10¹⁶ cm⁻³ | 200 nm | |
| AlGaAs | layer | | | |
| un-GaAs | 4-period MQW | ≦1 × 10¹⁵ cm⁻³ | 50 nm | ×4 |
| un- | buffer layer | ≦1 × 10¹⁶ cm⁻³ | 50 nm | periods |
| AlGaAs | | | | |
| un-GaAs | GaAs buffer | ≦1 × 10¹⁵ cm⁻³ | 200 nm | |
| | layer | | | |
| GaAs | Substrate | | | |

Further, for the purpose of forming an integrated device, a PHEMT device 103, a sort of field effect transistor, is formed on the semiconductor laminate prepared so far.

As the PHEMT device per se, any usual device may suffice. Specific examples are as shown below. That is, on the semiconductor laminate prepared as described above, a lower AlGaAs carrier supply layer, a lower GaAs/AlGaAs spacer layer, an InGaAs channel layer, an upper AlGaAs/GaAs spacer layer, an upper AlGaAs carrier supply layer, an AlGaAs schottky layer, and a GaAs cap layer are epitaxially grown sequentially. A portion of the cap layer is selectively etched to expose a portion of the schottky layer. Then, a source electrode and a drain electrode are formed on the left cap layer, and a gate electrode is formed on the exposed schottky layer to complete the PHEMT device 103, a sort of field effect transistor.

A groove-like region adjacent to the PHEMT device 103 is etched up to the middle of the buffer layer 102 to form a device isolation region 105. The width of the groove may be a usual width. That is, in this embodiment, the width is about 10 μm. A mesa-resistor element 104 is formed by using a mesa portion adjacent to the device isolation region 105. The mesa-resistor element 104 may be formed by using the layer structure of the PHEMT device 103 as it is, or by re-growing a layer structure for the resistor element thereon while partially or entirely removing the structure of the PHEMT device, or without removing it.

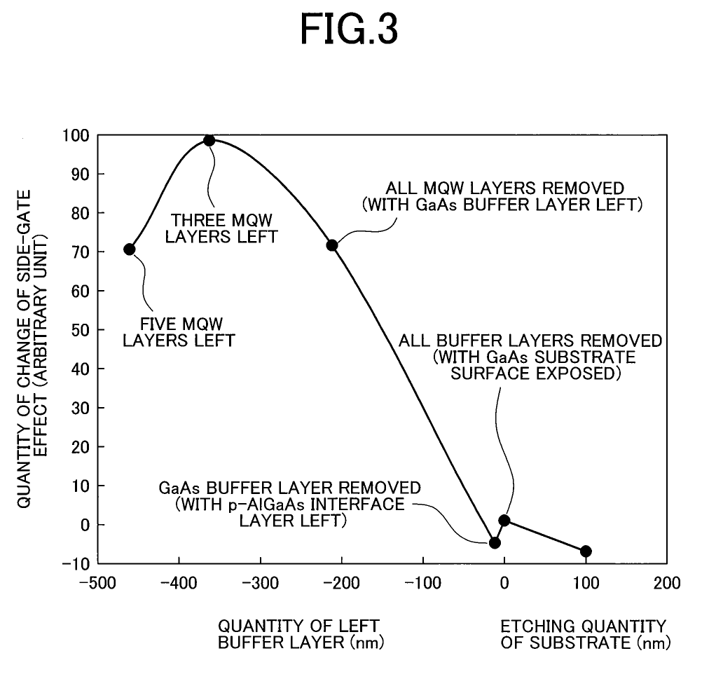

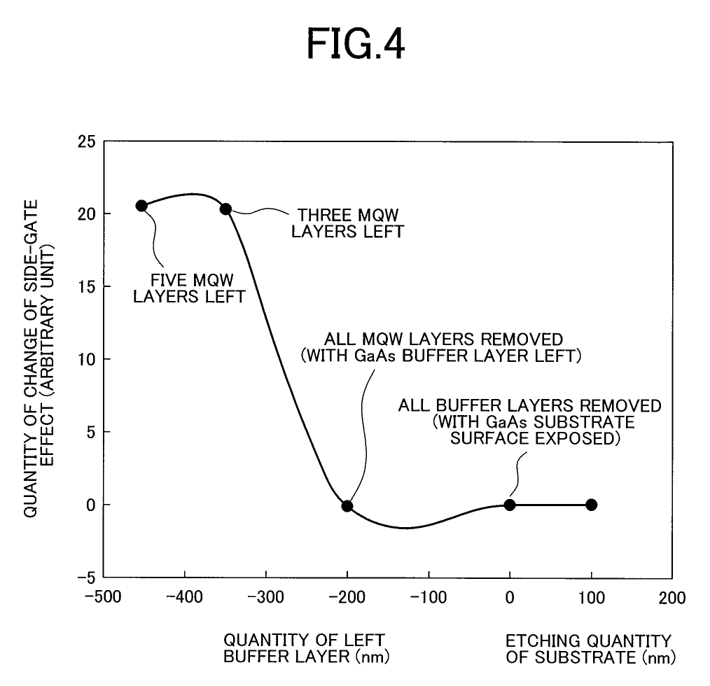

The relation between the depth of the groove and the degree of the sidegating effect of the PHEMT device 103 upon application of a voltage to the resistor element 104 in this example was investigated. FIG. 4 shows the result of 2-dimensional device simulation regarding the subject. FIG. 4 shows an example where the application voltage is −10V. Also in FIG. 4, like the example in FIG. 3, the horizontal axis shows the depth of the groove 105 as a quantity of the buffer layer left in a region where the buffer layer 102 is left and as a etching quantity of the substrate in a case where the groove reaches as far as the inside of the substrate. The vertical axis shows the quantity of change of the sidegating effect by an arbitrary unit.

In the simulation, while a deep energy level present in the energy band near the intermediate portion of the GaAs energy forbidden band referred to as EL2 is introduced into the GaAs substrate, such a deep energy level is not introduced to the buffer layer but only a shallow acceptor energy level is introduced. In FIG. 4, “Five MQW layers left,” “Three MQW layers left,” “MQW removed,” “all buffer layers removed,” etc. respectively show results in a case of leaving five MQW layers, in a case of leaving three MQW layers, in a case of removing all MQW layers, and in a case of removing all buffer layers.

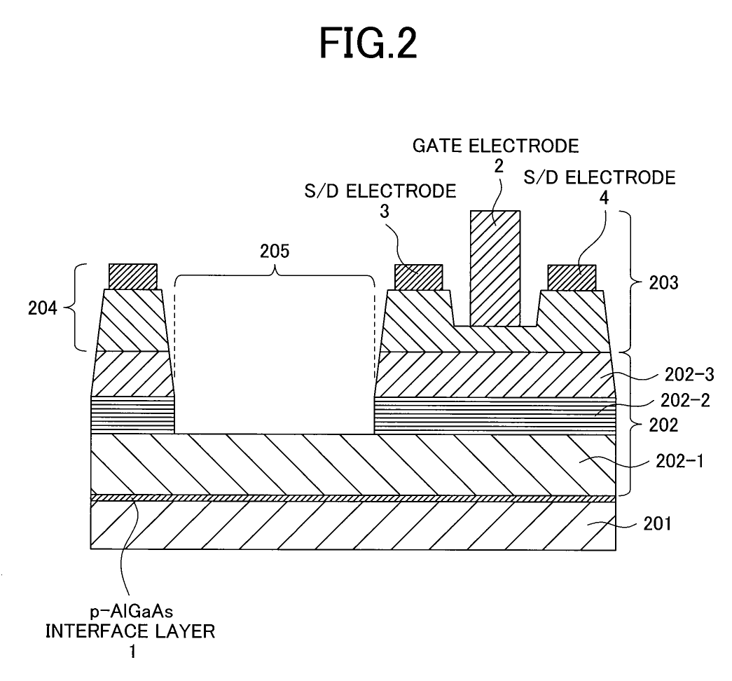

In the conventional structure, the sidegating effect is caused by way of the GaAs buffer layer as shown in FIG. 2. That is, the sidegating effect is caused also in a case of removing all MQW layers.

Also in this embodiment, in a case of conducting device isolation while leaving the MQW buffer layer, the sidegating effect is caused. However, when the buffer layer is removed up to the MQW buffer layer including itself and device isolation is conducted while leaving the GaAs buffer layer, the sidegating effect is decreased drastically. This is because conduction electrons do not stay at the GaAs/AlGaAs interface. That is, it can be understood that the sidegating effect by way of the GaAs buffer layer can be suppressed with the buffer layer left according to the invention.

In this embodiment, a GaAs substrate is used for the substrate, and a GaAs/AlGaAs laminate structure is used as the buffer layer, but InGaP may be used instead of GaAs, and InGaAlP may be used instead of AlGaAs for the buffer layer. For the buffer layer in this embodiment, a multi-layer structure containing thin, alternately stacked films is used; however, it may be a 2-layered structure where a GaAs or an InGaP layer is formed adjacently to the substrate, on which layer AlGaAs or InGaAlP is formed. Alternatively, the buffer layer may be a single-layer film of AlGaAs or InGaAlP. Further, an InP substrate may be used for the substrate, and a multi-layer film having two layers or more and comprising InGaAs/InGaAlAs, InGaAs/InGaAsP, or InGaAs/InGaAlAsP may also be used for the buffer layer, or a single-layer film comprising InGaAlAs, InGaAsP, InGaAlAsP, or InP may also be used for the buffer layer.

Further, it may be a GaN-type field effect transistor switch manufactured by using a sapphire substrate, a gallium nitride substrate, a silicon carbide substrate, or a silicon substrate for the substrate and using a multi-layered film having two layers or more and comprising GaN/AlGaN or GaN/AlN for the buffer layer.

In the buffer layer, a p-typed doping layer with a thickness of 5 nm to 100 nm and a carrier concentration of 1×10¹⁶ cm⁻³ to 1×10¹⁸ cm⁻³ may be disposed with an aim of suppressing a buffer leakage current between source and drain electrodes.

In this embodiment, while a PHEMT is used for the field effect transistor, other field effect transistors, for example, an MESFET (metal semiconductor field effect transistor) or an HIGFET (hetero-structure insulated-gate field effect transistor) may also be used.

In this embodiment, while description has been made on a case in which a device acting as a sidegate for the field effect transistor in question is a mesa-resistor element, the transistor may be other field effect transistors. Alternatively, it may also be a schottky diode. This also applies to the subsequent embodiments.

In this embodiment, description has been made on a case of forming the inter-device isolation region by etching to remove a layer structure forming the PHEMT device, that is, a channel layer, a carrier supply layer, and a layer forming gate, source and drain electrodes, the device isolation region may also be formed by ion implantation while leaving the layer structure of the PHEMT device. In this case, a defect energy level is introduced by ion implantation, and the Fermi level is subjected to pinning in the energy forbidden band to make the resistance higher. The condition for the energy, etc. upon ion implantation may be set such that the ion penetration depth defined as: ion projection range (Rp)+standard deviation (ΔRp), is made deeper than the region where the MQW buffer layer is present. Further, when the peak concentration of the ions to be implanted is 1×10¹⁷ cm⁻³ or more, a defect energy level concentration sufficient to cause pinning of the Fermi level is obtained. As the species of planted ions, oxygen, boron, helium, nitrogen, chromium, iron, ruthenium, etc. may be used.

On the other hand, when hydrogen is used as an ion species, pinning of the Fermi level does not occur in the energy forbidden band since a deep energy level is not formed sufficiently (although donors and acceptors at a shallow portion of the MQW layer are inactivated). Therefore, the phenomenon that the carriers move and stay at the potential barrier of the MQW is not suppressed, thereby causing the sidegating effect. The same applies to the case of using fluorine for an ion species. Accordingly, when ions for ion implantation is at least one member selected from the group consisting of hydrogen ions and fluorine ions, it is important that the buffer layer at least in the inter-device isolation region has a constitution not including a quantum well structure.

### Second Embodiment

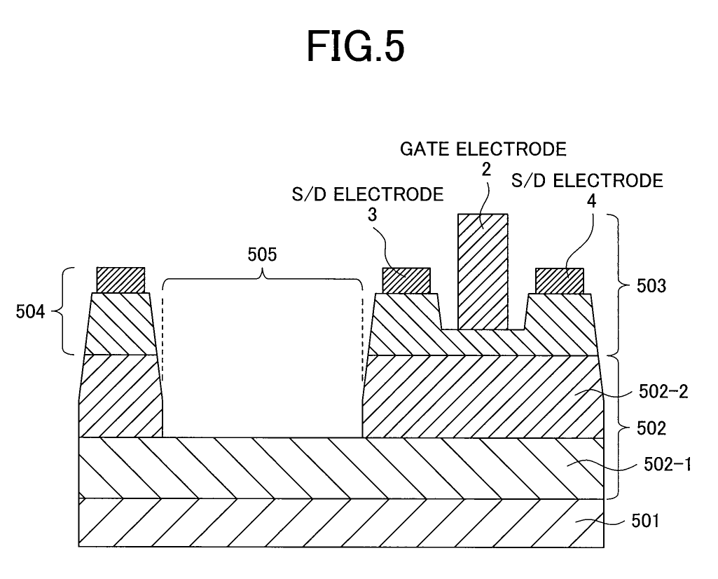

A second embodiment of the invention is to be described with reference to FIG. 5. FIG. 5 is a cross sectional view of the main portion of this embodiment. This is an example of using a buffer layer with a 2-layered structure. That is, this embodiment is a portion of an HEMT switch manufactured by forming a buffer layer 502 with an AlGaAs/GaAs 2-layer structure on a GaAs substrate 501, on which buffer layer a PHEMT device 503 having a channel comprising InGaAs and a resistance device 504, etc. are integrated with the resistance device 504 placed adjacently to the PHEMT device.

Since the constitution of this embodiment does not include the MQW structure, the manufacturing process is simpler and more convenient. Further, hydrogen ions or fluorine ions can also be used for forming the device isolation region. As described above, a more extended range of techniques is applicable to this embodiment, which provides a large margin in the design for various demands for characteristics associated with the semiconductor integrated circuit device.

Table 3 shows the structure of the buffer layer 502. The buffer layer is obtained by forming a GaAs buffer layer 502-1 with a 200 nm thickness on a GaAs substrate, on which buffer layer an AlGaAs buffer layer 502-2 with a 200 nm thickness is formed. A PHEMT device 503 is mounted on the buffer layer 502-2.

TABLE 3

| | Name for epitaxial | Carrier | |
|---|---|---|---|
| Material | layer | concentration | Thickness |
| un-AlGaAs | AlGaAs buffer layer | ≦1 × 10¹⁶ cm⁻³ | 200 nm |
| un-GaAs | GaAs buffer layer | ≦1 × 10¹⁵ cm⁻³ | 200 nm |
| GaAs | Substrate | | |

As the PHEMT device per se, any usual device may suffice. Specific examples are as shown below. That is, on the semiconductor laminate prepared as described above, a lower AlGaAs carrier supply layer, a lower GaAs/AlGaAs spacer layer, an InGaAs channel layer, an upper AlGaAs/GaAs spacer layer, an upper AlGaAs carrier supply layer, an AlGaAs schottky layer, and a GaAs cap layer are epitaxially grown sequentially. A portion of the cap layer is selectively etched to expose a portion of the schottky layer. Then, a source electrode 3 (or 4) and a drain electrode 4 (or 3) are formed on the left cap layer, and a gate electrode 2 is formed on the exposed schottky layer to complete the PHEMT device 503, a sort of field effect transistor.

A region adjacent to the PHEMT device 503 is etched up to the middle of the buffer layer 502 to form a device isolation region 505. A mesa-resistor element 504 is formed by using a mesa portion adjacent to the device isolation region 105. The mesa-resistor element 104 may be formed by using the layer structure of the PHEMT device 503 as it is, or by re-growing a layer structure for the resistor element thereon while partially or entirely removing the structure of the PHEMT device, or without removing it.

Since the hetero-interface formed in the buffer layer of this embodiment does not form a potential barrier upon conduction of electrons to the substrate (501), electrons do not accumulate in the buffer layer. Accordingly, the sidegating effect is suppressed not depending on the depth forming the device isolation region.

In this embodiment, while the GaAs substrate is used for the substrate and the two-layered film comprising GaAs/AlGaAs is used for the buffer layer, InGaP may be used instead of GaAs and InGaAlP may be used instead of AlGaAs for the buffer layer. While the 2-layered structure is used for the buffer layer in this example, it may be a single-layer film of AlGaAs or InGaAlP adjacent to the substrate.

Further, an InP substrate may be used for the substrate, and a laminate film with two layers comprising InGaAs/InGaAlAs, InGaAs/InGaAsP, or InGaAs/InGaAlAsP may be used for the buffer layer. Alternatively, a single-layer film comprising InGaAlAs, InGaAsP, InGaAlAsP or InP may also be used. Further, it may be a GaN-type field effect transistor switch manufactured by using a sapphire substrate, a gallium nitride substrate, a silicon carbide substrate, or a silicon substrate and a two-layer film comprising GaN/AlGaN or GaN/AlN, and a single-layer film comprising AlGaN or AlN for the buffer layer.

In the buffer layer, a p-typed doping layer with a thickness of 5 nm to 100 nm and a carrier concentration of 1×10¹⁶ cm⁻³ to 1×10¹⁸ cm⁻³ may be disposed with an aim of suppressing a buffer leakage current between source and drain electrodes.

In this embodiment, while a PHEMT is used for the field effect transistor, other field effect transistors, for example, an MESFET or an HIGFET may also be used.

In this embodiment, while description has been made on a case where the element acting as a sidegate for the field effect transistor in question is a mesa resistance element, the transistor may be other field effect transistors. Alternatively, it may be a schottky diode.

In this embodiment, while description has been made on a case in which an inter-device isolation region is formed by etching to remove a layer structure forming the PHEMT device, that is, a channel layer, a carrier supply layer, and a layer forming gate, source and drain electrodes, the device isolation region may also be formed by ion implantation while leaving the layer structure of the PHEMT device. As the ion species to be implanted in this case, hydrogen, fluorine, oxygen, boron, helium, nitrogen, chromium, iron, ruthenium, etc. are used. Since the electric resistance of the layered structure of the PHEMT device increases by the ion implantation to electrically isolate the devices and the potential barrier at the heterojunction interface to accumulate electrons is not present in the buffer layer, the sidegating effect by way of the buffer layer in the inter-device isolation region is suppressed.

While the statement has been made to the effect that hydrogen is not suitable as an ion species in the first embodiment, since the potential barrier causing accumulation of carriers in the buffer layer is not originally present in the structure of this embodiment, use of hydrogen or fluorine causes no problem.

### Third Embodiment

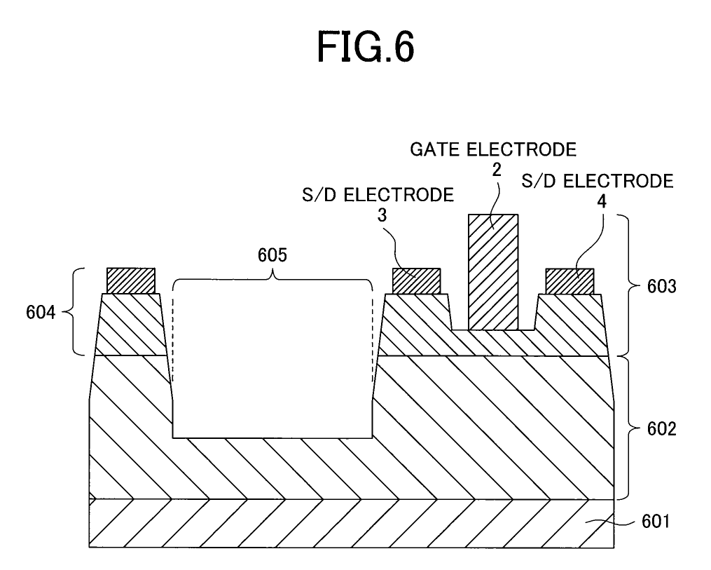

A third embodiment of the invention is to be described with reference to FIG. 6. FIG. 6 is a cross sectional view of the main portion of this embodiment. This embodiment is an example of using a buffer layer with a single-layer structure. That is, this embodiment is a portion of an HEMT switch manufactured by forming a buffer layer 602 with an AlGaAs single-layer structure on a GaAs substrate 601, on which buffer layer a PHEMT device 603 having a channel comprising InGaAs and a resistance device 604, etc. are integrated with the resistance device placed adjacently to the PHEMT device.

In this example, since the buffer layer is of a single-layered structure, the epitaxial structure is simple, manufacturing involved is easy, and hydrogen ions or fluorine ions can also be used for the formation of the inter-device isolation region as in the second embodiment. Also, although this embodiment adopts the buffer layer of a single-layered structure, it is important that the discontinuity of the electrostatic potential at the hetero-compound semiconductor junction interface formed at the interface between the buffering semiconductor layer and the semiconductor substrate is such that the electrostatic potential of the buffering compound semiconductor layer on the side of the substrate is lower than the potential on the side opposite to the substrate for the majority carriers during operation of the field effect transistor, as featured by the invention.

Table 4 shows the structure of the buffer layer. An AlGaAs buffer layer 602 with a 400 μm thickness is formed on a GaAs substrate (601) to form the buffer layer, and a PHEMT device 603 is mounted thereon.

TABLE 4

| | Name for epitaxial | Carrier | |
|---|---|---|---|
| Material | Layer | concentration | Thickness |
| un-AlGaAs | AlGaAs buffer layer | ≦1 × 10¹⁶ cm⁻³ | 400 nm |
| GaAs | Substrate | | |

As the PHEMT device per se, any usual device may suffice. Specific examples are as shown below. That is, on the semiconductor laminate prepared as described above, a lower AlGaAs carrier supply layer, a lower GaAs/AlGaAs spacer layer, an InGaAs channel layer, an upper AlGaAs/GaAs spacer layer, an upper AlGaAs carrier supply layer, an AlGaAs schottky layer, and a GaAs cap layer are epitaxially grown sequentially. A portion of the cap layer is selectively etched to expose a portion of the schottky layer. Then, a source electrode and a drain electrode are formed on the left cap layer and a gate electrode is formed on the exposed schottky layer to complete a PHEMT device 603, a sort of field effect transistor.

A region adjacent to the PHEMT device 603 is etched up to the middle of the buffer layer 602 to form a device isolation region 605. A mesa-resistor element 604 is formed by using a mesa portion adjacent to the device isolation region 605. The mesa-resistor element 604 may be formed by using the layer structure of the PHEMT device 603 as it is, or by re-growing a layer structure for the resistor element thereon while partially or entirely removing the structure of the PHEMT device, or without removing it.

Since the hetero-interface formed in the buffer layer of this example does not form a potential barrier upon conduction of electrons to the substrate, electrons do not accumulate in the buffer layer. Accordingly, the sidegating effect is suppressed not depending on the depth forming the device isolation region.

In this example, while a GaAs substrate is used for the substrate and an AlGaAs single-layer structure is used for the buffer layer, InGaAlP may be used instead of AlGaAs for the buffer layer. Further, an InP substrate may be used for the substrate, and a single-layer film comprising InGaAlAs, InGaAsP, InGaAlAsP, or InP may also be used. Alternatively, it may be a GaN-type field effect transistor switch manufactured by using a sapphire substrate, a gallium nitrate substrate, a silicon carbide substrate, or a silicon substrate and a single-layered film comprising AlGaN or AlN for the buffer layer.

In the buffer layer, a p-typed doping layer with a thickness of 5 nm to 100 nm and a carrier concentration of 1×10¹⁶ cm⁻³ to 1×10¹⁸ cm⁻³ may be disposed with an aim of suppressing a buffer leakage current between source and drain electrodes.

While a PHEMT is used in this example as the field effect transistor, other field effect transistors, for example, an MESFET or an HIGFET may also be used.

In this embodiment, while description has been made on a case where the element acting as a sidegate for the field effect transistor in question is a mesa resistance element, the transistor may be other field effect transistors. Alternatively, it may be a schottky diode.

In this embodiment, while description has been made on a case in which an inter-device isolation region is formed by etching to remove a layer structure forming the PHEMT device, that is, a channel layer, a carrier supply layer, and a layer forming gate, source and drain electrodes, the device isolation region may also be formed by ion implantation while leaving the layer structure of the PHEMT device. As the ion species to be implanted in this case, hydrogen, fluorine, oxygen, boron, helium, nitrogen, chromium, iron, ruthenium, etc. are used. Since the electric resistance of the layered structure of the PHEMT device increases by the ion implantation to electrically isolate the devices and the potential barrier at the heterojunction interface to accumulate electrons is not present in the buffer layer, the sidegating effect by way of the buffer layer in the inter-device isolation region is suppressed.

While the statement has been made to the effect that hydrogen is not suitable as an ion species in Example 1, since a potential barrier causing accumulation of carriers in the buffer layer is not originally present in the structure of this embodiment, use of hydrogen or fluorine causes no problem.

The present invention has been described by way of the various embodiments thus far. According to the invention, as a representative application example, a field effect transistor switch, e.g. a field effect transistor switch with less harmonic distortion in antenna output signals can be manufactured easily. Further, according to the application of the invention, mutual modulation distortion can be decreased, for example, in a wide-band CDMA system mobile telephone using a semiconductor integrated circuit device having a plurality of semiconductor electronic members including a field effect transistor.

The invention has been described specifically, and various embodiments of field effect transistor switches as a main application example are to be described below.

(1) A field effect transistor switch for an integrated device in which a buffer layer is formed on a substrate, and a plurality of devices manufactured by using semiconductor layers laminated on the buffer layer are integrated, wherein device isolation is conducted by physically removing the semiconductor layer between the devices at least up to a portion of the buffer layer, and discontinuity of the electrostatic potential at the interface between the buffer layer and the substrate and/or the interface of heterojunction formed at the interface between the semiconductor layers forming the buffer layer in the device isolation region is such that the electrostatic potential on the side of the substrate is lower than the potential on the surface side for majority carriers during operation of the field effect transistor.

(2) A field effect transistor switch for an integrated device in which a buffer layer is formed on a substrate, and a plurality of devices manufactured by using semiconductor layers laminated on the buffer layer are integrated, wherein the device isolation is conducted by physically leaving at least partially or entirely the semiconductor layer and the buffer layer between the devices, and by ion implantation to the left semiconductor layer and the buffer layer, the buffer layer is present as deep as a region deeper than the penetration depth of the implanted ions defined as a sum of the ion projection range of the implanted ions and the standard deviation of the projection range, and discontinuity of the electrostatic potential at the interface between the buffer layer and the substrate and/or the interface of heterojunction formed at the interface between the semiconductor layers forming the buffer layer in the region deeper than the penetration depth of the implanted ions in the device isolation region is such that the electrostatic potential is lower on the side of the substrate than the side of the surface for majority carriers during operation of the field effect transistor.

(3) The field effect transistor switch according to (2) described above, wherein the peak concentration of the ions implanted for conducting inter-device isolation is 1×10¹⁷ cm⁻³ or higher.

(4) The field effect transistor switch according to (2) to (3) described above, wherein the ions for conducting inter-device isolation are oxygen ions, boron ions, helium ions, nitrogen ions, chromium ions, iron ions, or ruthenium ions.

(5) A field effect transistor switch for an integrated device in which a buffer layer is formed on a substrate, and a plurality of devices manufactured by using semiconductor layers laminated on the buffer layer are integrated, wherein the device isolation is conducted by physically leaving at least partially or entirely the semiconductor layer and the buffer layer between the devices and by hydrogen ion implantation to the left semiconductor layer and the buffer layer, and the discontinuity of the electrostatic potential at the interface present in the buffer layer physically left in the inter-device isolation region and at the interface of heterojunction formed at the interface between the buffer layer and the substrate is such that the electrostatic potential is lower on the side of the substrate than the side of the surface for majority carriers during operation of the field effect transistor.

(6) A field effect transistor switch for an integrated device in which a buffer layer is formed on a substrate, and a plurality of devices manufactured by using semiconductor layers laminated on the buffer layer are integrated, wherein the device isolation is conducted by physically leaving at least partially or entirely the semiconductor layer and the buffer layer between the devices and by fluorine ion implantation to the left semiconductor layer and the buffer layer, and the discontinuity of the electrostatic potential at the interface present in the buffer layer physically left in the inter-device isolation region and at the interface of heterojunction formed at the interface between the buffer layer and the substrate is such that the electrostatic potential is lower on the side of the substrate than the side of the surface for majority carriers during operation of the field effect transistor.

(7) The field effect transistor switch according to (1) to (6) described above, wherein a GaAs substrate is used for the substrate, and at least AlGaAs is contained in the buffer layer.

(8) The field effect transistor switch according to (1) to (6) described above, wherein an InP substrate is used for the substrate, and the buffer layer contains at least either of AlInAs, GaInAs, AlGaInAs, GaInAsP, or AlGaInAsP.

(9) The field effect transistor switch according to (1) to (6) described above, wherein a GaN substrate or a sapphire substrate is used as the substrate, and the buffer layer contains at least GaN, AlN, and AlGaN.

(10) The field effect transistor switch according to (1) to (6) described above, wherein the field effect transistor is an HEMT (high electron mobility transistor).

### DESCRIPTION FOR REFERENCES

101: GaAs substrate
102: buffer layer having an AlGaAs/GaAs laminate structure
103: PHEMT device
104: mesa resistor element
105: device isolation region
201: GaAs substrate
202: buffer layer having an AlGaAs/GaAs laminate structure
203: HEMT device
204: mesa resistor element
205: device isolation region
501: GaAs substrate
502: buffer layer having an AlGaAs/GaAs two-layered structure
503: PHEMT device
504: mesa resistor element
505: device isolation region
601: GaAs substrate
602: buffer layer having an AlGaAs/GaAs two-layered structure
603: PHEMT device
604: mesa resistance element
605: device isolation region

What is claimed is:

1. A semiconductor integrated circuit device at least having, on a substrate, a field effect transistor as a first electronic member and a second electronic member mounted in juxtaposition and an inter-device isolation region between the field effect transistor and the second electronic member by way of a buffering compound semiconductor layer, wherein
the buffering compound semiconductor layer is formed to have a thickness smaller than those in other regions, or the buffering compound semiconductor layer is not present in the inter-device isolation region, and the discontinuity of electrostatic potential formed at the hetero-compound semiconductor junction interface, which is at least either of the interface between the buffering semiconductor layer and the semiconductor substrate or the interface between the compound semiconductor layers to each other constituting the buffering compound semiconductor layer, is such that the electrostatic potential of the buffering compound semiconductor layer on the side of the substrate is lower than the potential on the side opposite to the substrate for majority carriers during operation of the field effect transistor.

2. The semiconductor integrated circuit device according to claim 1, wherein
the inter-device isolation region is a groove, and the buffering compound semiconductor layer at the bottom of the groove is formed to have a thickness smaller than those in other regions, or the buffering compound semiconductor layer is not present.

3. The semiconductor integrated circuit device according to claim 2, wherein
the inter-device isolation region is an inter-device isolation region formed by ion implantation, and the buffering compound semiconductor layer present in the device isolation region on the side of the substrate is formed to have a thickness smaller than those in other regions, or the buffering compound semiconductor layer is not present.

4. The semiconductor integrated circuit device according to claim 3, wherein
the device isolation region formed by ion implantation has a peak concentration of implanted ions of 1×10¹⁷ cm⁻³ or higher.

5. The semiconductor integrated circuit device according to claim 4, wherein
ions for ion implantation are at least one member selected from the group consisting of oxygen ions, boron ions, helium ions, nitrogen ions, chromium ions, iron ions, and ruthenium ions.

6. The semiconductor integrated circuit device according to claim 3, wherein
the buffering compound semiconductor layer at least in the inter-device isolation region does not contain a quantum well structure, and in the device isolation region to be formed by the ion implantation, ions for the ion implantation are at least one member selected from the group of hydrogen ions and fluorine ions.

7. The semiconductor integrated circuit device according to claim 1, wherein
the buffering compound semiconductor layer at least in the inter-device isolation region has a first compound semiconductor layer, a compound semiconductor layer of a multi-layered quantum well structure, and a second compound semiconductor layer.

8. The semiconductor integrated circuit device according to claim 1, wherein
the buffering compound semiconductor layer at least in the inter-device isolation region comprises a plurality of compound semiconductor layers not containing a quantum well structure.

9. The semiconductor integrated circuit device according to claim 1, wherein
the buffering compound semiconductor layer at least in the inter-device isolation region comprises a single compound semiconductor layer, and the discontinuity of the electrostatic potential at the hetero-compound semiconductor junction interface formed at the interface between the buffering semiconductor layer and the semiconductor substrate is such that the electrostatic potential of the buffering compound semiconductor layer on the side of the substrate is lower than the potential on the side opposite to the substrate for majority carriers during operation of the field effect transistor.

10. The semiconductor integrated circuit device according to claim 1, wherein
the substrate is a GaAs substrate, and the buffering compound semiconductor layer at least in the inter-device isolation region is at least one member selected from the group consisting of GaAs, AlGaAs, InGaAs, and InGaAlP.

11. The semiconductor integrated circuit device according to claim 1, wherein
the substrate is an InP substrate, and the buffering compound semiconductor layer at least in the inter-device isolation region is at least one member selected from the group consisting of AlInAs, GaInAs, AlGaInAs, GaInAsP, and AlGaInAsP.

12. The semiconductor integrated circuit device according to claim 1, wherein
the substrate is one member selected from the group consisting of a GaN substrate, a sapphire substrate, a silicon carbide substrate, and a silicon substrate, and the buffering compound semiconductor layer at least in the inter-device isolation region is at least one member selected from the group consisting of GaN, AlN, and AlGaN.

13. The semiconductor integrated circuit device according to claim 1, wherein
the field effect transistor as the first electronic member is an HEMT (high electron mobility transistor).

14. A semiconductor switching device constituted with a semiconductor integrated circuit device included wherein
the semiconductor integrated circuit device at least having, above a substrate, a field effect transistor as a first electronic member and a second electronic member mounted in juxtaposition and an inter-device isolation region between the field effect transistor and the second electronic member by way of a buffering compound semiconductor layer, wherein
the buffering compound semiconductor layer is formed to have a thickness smaller than those in other regions, or the buffering compound semiconductor layer is not present in the inter-device isolation region, and the discontinuity of electrostatic potential at the hetero-compound semiconductor junction interface, which is at least either of the interface between the buffering semiconductor layer and the semiconductor substrate or the interface between the compound semiconductor layers constituting the buffering compound semiconductor layer, is such that the electrostatic potential of the buffering compound semiconductor layer on the side of the substrate is lower than the potential on the side opposite to the substrate for majority carriers during operation of the field effect transistor.

15. The semiconductor switching device according to claim 14, wherein
the inter-device isolation region is a groove, and the buffering compound semiconductor layer at the bottom of the groove is formed to have a thickness smaller than those in other regions, or the buffering compound semiconductor layer is not present.

16. The semiconductor switching device according to claim 15, wherein
the inter-device isolation region is a device isolation region formed by ion implantation, and the buffering compound semiconductor layer present in the device-isolation region on the side of the substrate is formed to have a thickness smaller than those in other regions, or the buffering compound semiconductor layer is not present.

17. The semiconductor switching device according to claim 16, wherein
the device isolation region formed by ion implantation has a peak concentration of implanted ions of 1×10¹⁷ cm⁻³ or higher.

18. The semiconductor switching device according to claim 17, wherein
ions for the ion implantation are at least one member selected from the group consisting of oxygen ions, boron ions, helium ions, nitrogen ions, chromium ions, iron ions, and ruthenium ions.

19. The semiconductor switching device according to claim 18, wherein
the buffering compound semiconductor layer at least in the inter-device isolation region does not contain a quantum well structure, and in the device-isolation region to be formed by the ion implantation, ions for the ion implantation are at least one member selected from the group of hydrogen ions and fluorine ions.

20. The semiconductor switching device according to claim 14, wherein
the buffering compound semiconductor layer at least in the inter-device isolation region has a first compound semiconductor layer, a compound semiconductor layer of a multi-layered quantum well structure, and a second compound semiconductor layer.
